(19) United States
(12) Patent Application Publication
(10) Pub. No.: US 2025/0113708 A1
(43) Pub. Date: Apr. 3, 2025

(54) DISPLAY DEVICE AND MOTHER SUBSTRATE FOR DISPLAY DEVICE

(71) Applicant: Japan Display Inc., Tokyo (JP)

(72) Inventors: Naoya IWAHASHI, Tokyo (JP); Sho YANAGISAWA, Tokyo (JP); Hideyuki TAKAHASHI, Tokyo (JP); Ryota TAKASAKI, Tokyo (JP); Kazumi IIZAWA, Tokyo (JP)

(73) Assignee: Japan Display Inc., Tokyo (JP)

(21) Appl. No.: 18/899,440

(22) Filed: Sep. 27, 2024

(30) Foreign Application Priority Data
Sep. 29, 2023 (JP) 2023-170053

(51) Int. Cl. H10K 59/122

(52) U.S. Cl. CPC H10K 59/122

(57) ABSTRACT

According to one embodiment, a display device includes a lower electrode in a display area, a rib layer in the display area and a surrounding area, a first partition above the rib layer in the display area, an organic layer, an upper electrode and a second partition above the rib layer in the surrounding area. The rib layer has a pixel aperture. The organic layer is in contact with the lower electrode through the pixel aperture. The upper electrode covers the organic layer and is in contact with the first partition. Each of the partitions includes a lower portion and an upper portion. The second partition includes segments spaced apart from each other. Each of the segments has apertures.

### CROSS-REFERENCE TO RELATED APPLICATIONS

This application is based upon and claims the benefit of priority from Japanese Patent Application No. 2023-170053, filed Sep. 29, 2023, the entire contents of which are incorporated herein by reference.

### FIELD

Embodiments described herein relate generally to a display device and a mother substrate for a display device.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of a display panel along the III-III line of FIG. 2.

FIG. 4 is the schematic plan view of a mother substrate according to the first embodiment.

FIG. 5 is a schematic plan view of part of the mother substrate according to the first embodiment.

FIG. 6 is a schematic plan view showing an example of a partition (second partition) according to the first embodiment.

FIG. 7 is the schematic cross-sectional view of the mother substrate along the VII-VII line of FIG. 6.

FIG. 8A is a schematic cross-sectional view showing the process of forming panel portions in the mother substrate.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 9 is the schematic plan view of a plurality of segments according to a second embodiment.

FIG. 10 is the schematic plan view of a plurality of segments according to a third embodiment.

FIG. 11 is the schematic plan view of a plurality of segments according to a fourth embodiment.

FIG. 12 is the schematic plan view of a plurality of segments according to a fifth embodiment.

FIG. 13 is the schematic plan view of a plurality of segments according to a sixth embodiment.

FIG. 14 is the schematic plan view of a plurality of segments according to a seventh embodiment.

FIG. 15 is the schematic plan view of a plurality of segments according to an eighth embodiment.

FIG. 16 is a schematic plan view showing another example of the layout form of the segments according to the eighth embodiment.

FIG. 17 is a schematic plan view showing yet another example of the layout form of the segments according to the eighth embodiment.

### DETAILED DESCRIPTION

In general, according to one embodiment, a display device comprises a lower electrode, a rib layer, a first partition, an organic layer, an upper electrode and a second partition. The lower electrode is provided in a display area. The rib layer is provided in the display area and a surrounding area around the display area and has a pixel aperture overlapping the lower electrode. The first partition is provided above the rib layer in the display area. The organic layer is in contact with the lower electrode through the pixel aperture and emits light based on application of voltage. The upper electrode covers the organic layer and is in contact with the first partition. The second partition is provided above the rib layer in the surrounding area. Each of the first partition and the second partition includes a lower portion provided above the rib layer and an upper portion having an end portion protruding from a side surface of the lower portion. Further, the second partition includes a plurality of segments spaced apart from each other. Each of the segments has a plurality of apertures.

According to another embodiment, a mother substrate for a display device comprises a plurality of panel portions, a margin area around the panel portions, a lower electrode, a rib layer, a first partition, an organic layer, an upper electrode and a second partition. Each of the panel portions includes a display area and a surrounding area around the display area. The lower electrode is provided in the display area. The rib layer has a pixel aperture overlapping the lower electrode. The first partition is provided above the rib layer in the display area. The organic layer is in contact with the lower electrode through the pixel aperture and emits light based on application of voltage. The upper electrode covers the organic layer and is in contact with the first partition. The second partition is provided above the rib layer in at least one of the surrounding area and the margin area. Each of the first partition and the second partition includes a lower portion provided above the rib layer and an upper portion having an end portion protruding from a side surface of the lower portion. Further, the second partition includes a plurality of segments spaced apart from each other. Each of the segments has a plurality of apertures.

These configurations can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

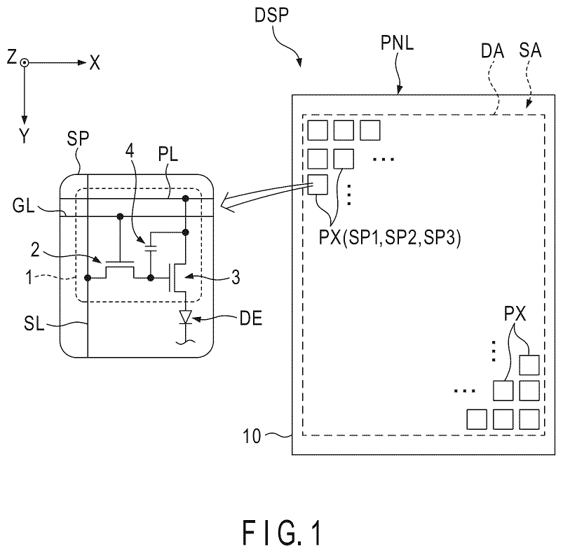

FIG. 1 is a diagram showing a configuration example of a display device DSP according to a first embodiment. The display device DSP comprises a display panel PNL including an insulating substrate 10. The display panel PNL has a display area DA which displays an image, and a surrounding area SA around the display area DA. The substrate 10 may be glass or a resinous film having flexibility.

In the present embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply scanning signals to the pixel circuits 1 of subpixels SP, a plurality of signal lines SL which supply video signals to the pixel circuits 1 of subpixels SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

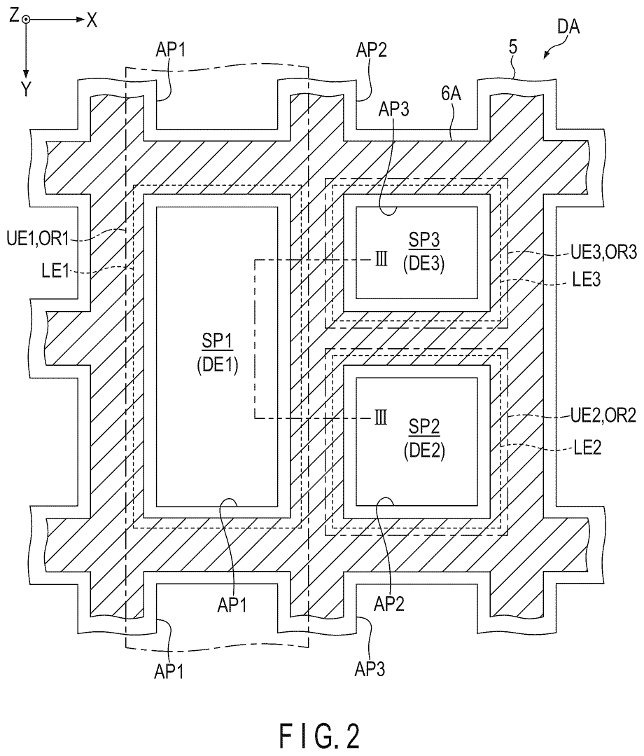

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A overlaps the rib layer 5 as a whole and has a planar shape similar to that of the rib layer 5. In other words, the partition 6A has an aperture in each of subpixels SP1, SP2 and SP3. From another viewpoint, the rib layer 5 and the partition 6A have grating shapes as seen in plan view and surround each of the display elements DE1, DE2 and DE3. The partition 6A functions as lines which apply common voltage to the upper electrodes UE1, UE2 and UE3.

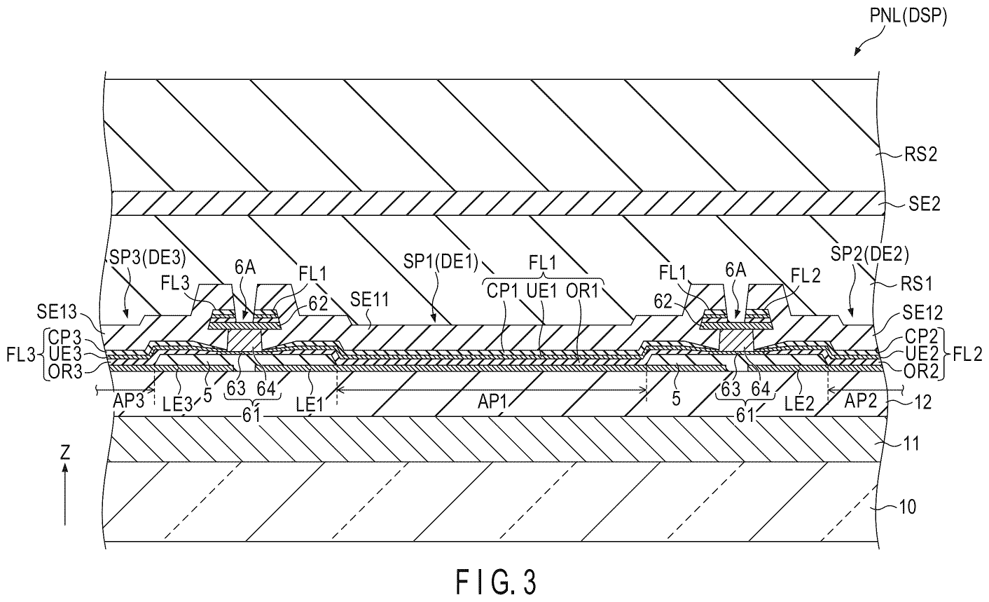

FIG. 3 is the schematic cross-sectional view of the display panel PNL along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6A (in other words, the portion which constitutes the display element DE1). Similarly, the stacked film FL2 is partly located on the upper portion 62. This portion is spaced apart from, of the stacked film FL2, the portion located around the partition 6A (in other words, the portion which constitutes the display element DE2). Further, the stacked film FL3 is partly located on the upper portion 62. This portion is spaced apart from, of the stacked film FL3, the portion located around the partition 6A (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6A around subpixel SP1. The sealing layer SE12 continuously covers the cap layer CP2 and the partition 6A around subpixel SP2. The sealing layer SE13 continuously covers the cap layer CP3 and the partition 6A around subpixel SP3.

In the example of FIG. 3, the stacked film FL1 and sealing layer SE11 located on the partition 6A between subpixels SP1 and SP2 are spaced apart from the stacked film FL2 and sealing layer SE12 located on this partition 6A. The stacked film FL1 and sealing layer SE11 located on the partition 6A between subpixels SP1 and SP3 are spaced apart from the stacked film FL3 and sealing layer SE13 located on this partition 6A.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (Siox) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6A comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage.

Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

When the display device DSP is manufactured, a large mother substrate in which a plurality of areas (panel portions) each corresponding to the display panel PNL are formed is prepared. A configuration which could be applied to this mother substrate is explained below.

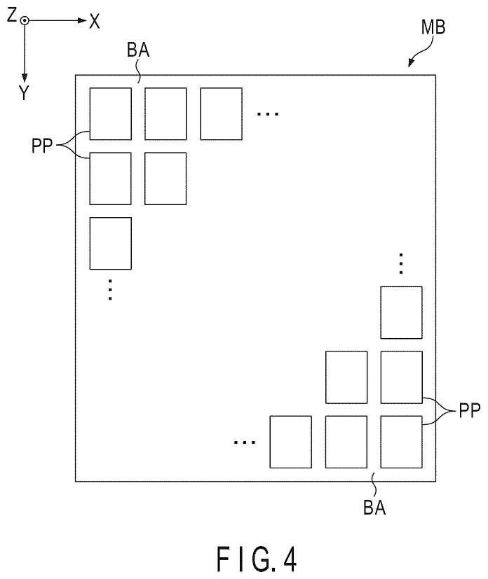

FIG. 4 is the schematic plan view of a mother substrate MB (a mother substrate for a display device) according to the embodiment. The mother substrate MB is, for example, rectangular as shown in the figure. However, the mother substrate MB may have another shape such as a circle. The mother substrate MB comprises a plurality of panel portions PP provided in matrix, and a margin area BA around these panel portions PP.

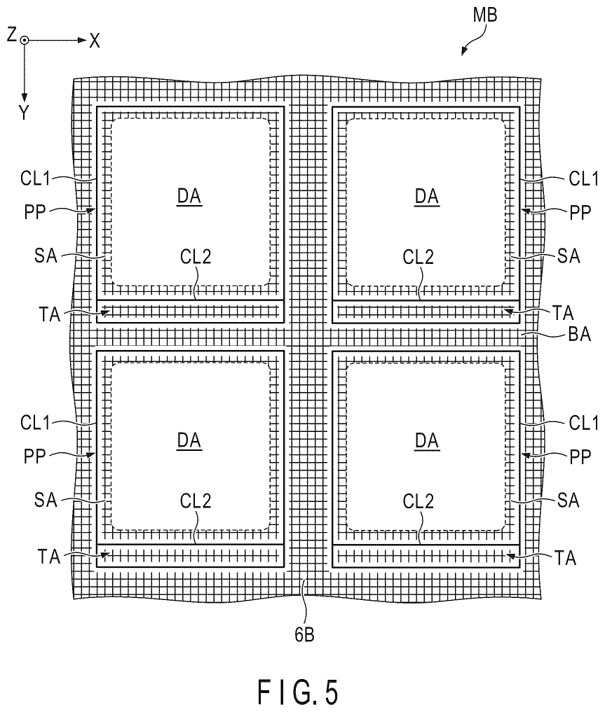

FIG. 5 is the schematic plan view of part of the mother substrate MB. The outer shape of each panel portion PP corresponds to a cut line CL1 for cutting the panel portion PP from the mother substrate MB.

Each panel portion PP has the display area DA and surrounding area SA described above. Further, each panel portion PP has an inspection area TA. In the inspection area TA, an inspection pad for inspecting the operation of the display panel PNL is provided.

A cut line CL2 is formed between the surrounding area SA and the inspection area TA. When the display device DSP is manufactured, first, each panel portion PP is cut out from the mother substrate MB along the cut line CL1. Further, the above inspection is performed for the cut panel portion PP. After this inspection, the inspection area TA is separated from the panel portion PP along the cut line CL2.

In this embodiment, a partition (second partition) 6B is provided in the margin area BA, the surrounding area SA and the inspection area TA. In FIG. 5, a grating pattern is added to the area in which the partition 6B is provided. It should be noted that this grating pattern does not show the actual shape of the partition 6B.

To effectively cut out the panel portions PP, it is preferable that the partition 6B should not be provided in the cut lines CL1. Similarly, it is preferable that the partition 6B should not be provided in the cut lines CL2.

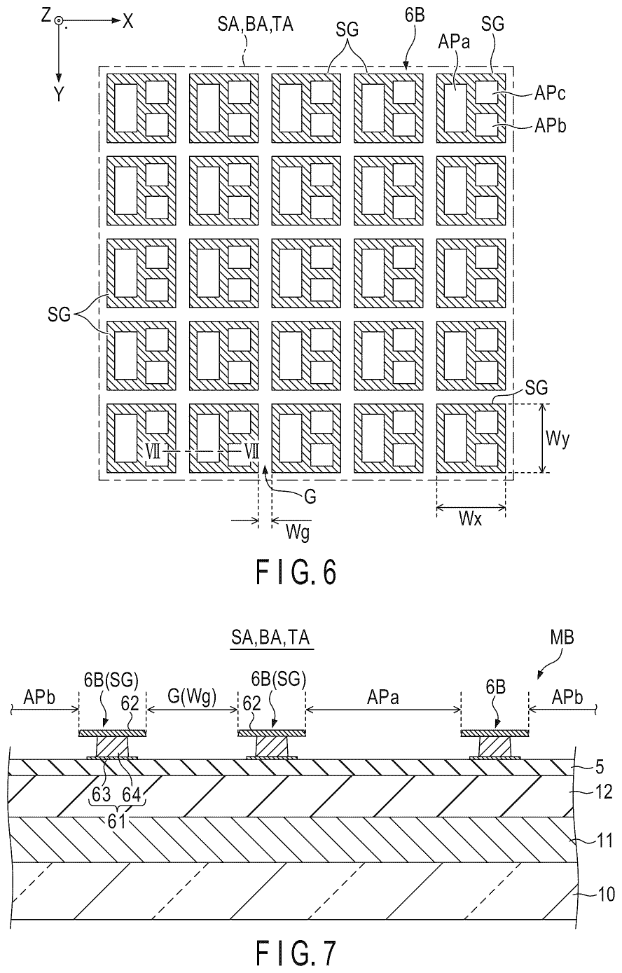

FIG. 6 is a schematic plan view showing an example of the partition 6B. The partition 6B has a plurality of segments SG spaced apart from each other. In the example of FIG. 6, these segments SG have the same shape and are arranged in the X-direction and the Y-direction. Each segment SG is a quadrangle (a rectangle or a square) which has two sides extending in the X-direction and two sides extending in the Y-direction.

Each segment SG has three apertures APa, APb and APc. The apertures APa, APb and APc are provided in line with, for example, a layout similar to that of the pixel apertures AP1, AP2 and AP3. Specifically, in the example of FIG. 6, each of the apertures APb and APc is adjacent to the aperture APa in the X-direction. Further, the apertures APb and APc are arranged in the Y-direction. The apertures APb and APc are smaller than the aperture APa. The sizes of the apertures APb and APc are, for example, equal to each other. However, they may be different from each other.

A gap G is defined between adjacent segments SG. In the example of FIG. 6, the gap G has a grating shape which includes portions extending in the X-direction and portions extending in the Y-direction.

Each segment SG has width Wx in the X-direction and has width Wy in the Y-direction. The gap G has uniform width Wg as a whole. It should be noted that the gap G may partially have different widths.

Widths Wx and Wy are, for example, greater than or equal to the width of each pixel PX in the X-direction and the width of each pixel PX in the Y-direction, respectively. However, width Wx or Wy is not limited to this example. Widths Wx and Wy may be equal to each other or may be different from each other. Width Wg is, for example, less than widths Wx and Wy (Wg<Wx, Wy). Width Wg should be preferably less than or equal to 40 μm (Wg≤40 μm). By this configuration, the effect of preventing the removal of the stacked films FL1, FL2 and FL3 is enhanced as described later.

It should be noted that the segments SG having the shapes shown in FIG. 6 are not necessarily provided in the entire part of the margin area BA, the surrounding area SA and the inspection area TA. A segment (partition 6B) having another shape may be provided in at least part of the margin area BA, the surrounding area SA and the inspection area TA.

In addition, the shape of each segment SG is not limited to the rectangle shown in FIG. 6. The shape of each segment SG may be another polygonal shape or may be a shape including a curved outline. Further, the number of apertures provided in each segment SG or the shape of each aperture is not limited to the example of FIG. 6.

FIG. 7 is the schematic cross-sectional view of the mother substrate MB along the VII-VII line of FIG. 6. The partition 6B is provided on the rib layer 5 in a manner similar to that of the partition 6A. In the example of FIG. 7, the circuit layer 11 and the organic insulating layer 12 are provided between the rib layer 5 and the substrate 10. The circuit layer 11 or the organic insulating layer 12 may not be provided in at least part of the margin area BA, the surrounding area SA and the inspection area TA.

The partition 6B includes a lower portion 61 and an upper portion 62 in a manner similar to that of the partition 6A. Further, the lower portion 61 of the partition 6B includes a bottom layer 63 and a stem layer 64. In the partition 6B, similarly, the end portions of the upper portion 62 protrude from the side surfaces of the lower portion 61 (stem layer 64).

In the apertures APa, APb and APc and the gap G, the rib layer 5 is exposed from the partition 6B. Width Wg of the gap G described above corresponds to the distance between the upper portions 62 of the segments SG which are adjacent to each other via the gap G.

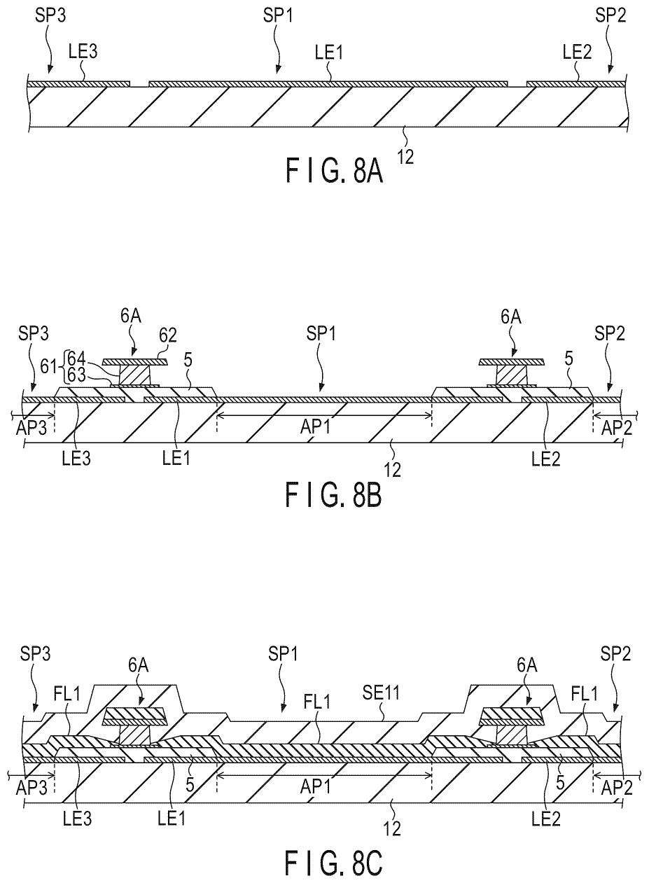

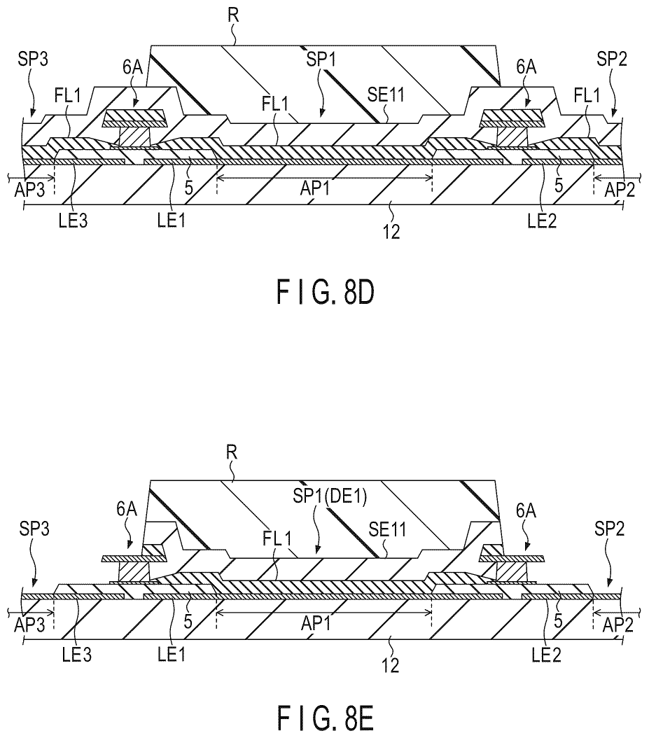

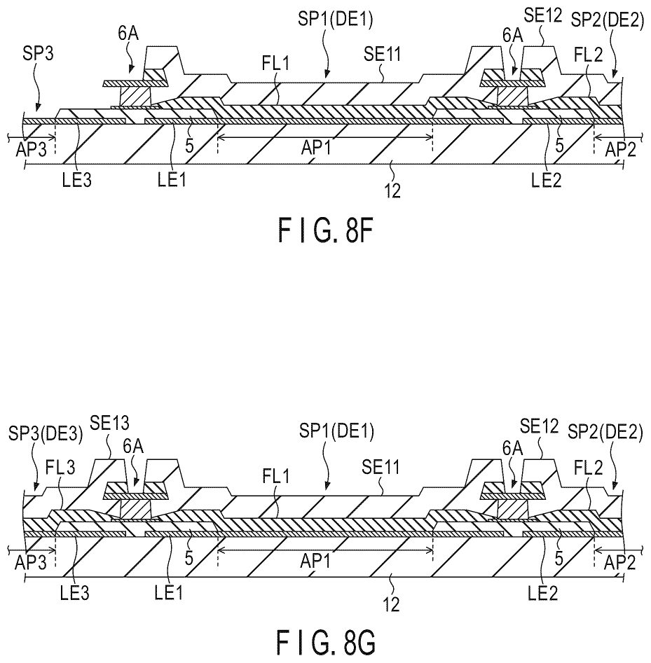

Now, this specification explains an example of the manufacturing method of the display device DSP. FIG. 8A to FIG. 8G are schematic cross-sectional views showing the process of forming the panel portions PP in the mother substrate MB. In FIG. 8A to FIG. 8G, the display area DA is mainly looked at, and the elements located under the organic insulating layer 12 are omitted.

To form the panel portions PP, first, the circuit layer 11 and the organic insulating layer 12 are formed on the substrate 10 of the mother substrate MB. Subsequently, as shown in FIG. 8A, the lower electrodes LE1, LE2 and LE3 are formed on the organic insulating layer 12.

Subsequently, the rib layer 5 and the partition 6A are formed as shown in FIG. 8B. The pixel apertures AP1, AP2 and AP3 of the rib layer 5 may be provided after the formation of the partition 6A or may be provided before the formation of the partition 6A. The partition 6B shown in FIG. 7 is formed in the same process as the partition 6A.

After the formation of the rib layer 5 and the partitions 6A and 6B, a process for forming the display elements DE1, DE2 and DE3 is performed. In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8C, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1.

The organic layer OR1, the upper electrode UE1 and the cap layer CP1 are formed by vapor deposition. The sealing layer SE11 is formed by chemical vapor deposition (CVD).

The stacked film FL1 and the sealing layer SE11 are formed in the entire mother substrate MB including the surrounding area SA, the inspection area TA and the margin area BA as well as the display area DA of each panel portion PP. The stacked film FL1 is divided into a plurality of portions by the partitions 6A and 6B having overhang shapes. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 8D, a resist R is provided on the sealing layer SE11. The resist R covers subpixel SP1 and part of the partition 6A around the subpixel.

Subsequently, as shown in FIG. 8E, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. For example, in the surrounding area SA, the inspection area TA and the margin area BA, the stacked film FL1 and the sealing layer SE11 are removed by this etching. This etching could include wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire mother substrate MB. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partitions 6A and 6B having overhang shapes. The sealing layer SE12 continuously covers the portions into which the stacked film FL2 is divided, and the partitions 6A and 6B. By patterning these stacked film FL2 and sealing layer SE2, the display element DE2 is formed in subpixel SP2 as shown in FIG. 8F. For example, in the surrounding area SA, the inspection area TA and the margin area BA, the stacked film FL2 and the sealing layer SE12 are removed by etching at the time of this patterning.

The display element DE3 is formed by a procedure similar to the procedures of the display elements DE1 and DE2. Specifically, when the display element DE3 is formed, the stacked film FL3 and the sealing layer SE13 are formed in the entire mother substrate MB. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The 1 sealing layer SE13 is formed by CVD. The stacked film FL3 is divided into a plurality of portions by the partitions 6A and 6B having overhang shapes. The sealing layer SE13 continuously covers the portions into which the stacked film FL3 is divided, and the partitions 6A and 6B. By patterning these stacked film FL3 and sealing layer SE13, the display element DE3 is formed in subpixel SP3 as shown in FIG. 8G. For example, in the surrounding area SA, the inspection area TA and the margin area BA, the stacked film FL3 and the sealing layer SE13 are removed by etching at the time of this patterning.

After the display elements DE1, DE2 and DE3 are formed, the resin layer RS1, sealing layer SE2 and resin layer RS2 shown in FIG. 3 are formed in order. Further, each panel portion PP is cut out from the mother substrate MB along the cut lines CL1.

Subsequently, inspection is performed for each panel portion PP. The inspection includes, for example, the lighting inspection of each of the display elements DE1, DE2 and DE3 using the inspection pad provided in the inspection area TA. After the inspection, the inspection area TA is cut along the cut line CL2. In this manner, the display panel PNL is completed.

It should be noted that at least one of the stacked films FL1, FL2 and FL3 may be left without being removed in the surrounding area SA, the inspection area TA and the margin area BA.

Now, this specification explains several effects obtained from the embodiment. When the display elements DE1, DE2 and DE3 are formed, the stacked films FL1, FL2 and FL3 are formed in the entire mother substrate MB. The stacked films FL1, FL2 and FL3 which are formed by vapor deposition have weak adherence to the base. Therefore, there is a possibility that the stacked films FL1, FL2 and FL3 are peeled from the base during the manufacturing process of the display device DSP. When this peeling expands, the stacked films FL1, FL2 and FL3 and the sealing layers SE11, SE12 and SE13 located thereon may be removed. Thus, they could be undesired particles.

In the display area DA, the stacked films FL1, FL2 and FL3 are divided into pieces by the partition 6A having a grating shape. Therefore, the stacked film FL1, FL2 or FL3 is not easily peeled from the base. Further, in this embodiment, the partition 6B is provided in the surrounding area SA, the inspection area TA and the margin area BA. By this configuration, the removal of the stacked films FL1, FL2 and FL3 is prevented in the surrounding area SA, the inspection area TA and the margin area BA as well.

In this embodiment, as shown in FIG. 6, the partition 6B includes a plurality of segments SG, and each segment SG has a plurality of apertures APa, APb and APc. In this configuration, since the stacked films FL1, FL2 and FL3 are divided into pieces in the surrounding area SA, the inspection area TA and the margin area BA, the effect of preventing the removal of the stacked films FL1, FL2 and FL3 is enhanced.

If the partition 6B is not divided into a plurality of segments SG and is provided in a wide range without any gap, the partition 6B forms a relatively large conductive body. In this case, electrostatic discharge (ESD) is easily caused by the partition 6B. If electrostatic discharge is caused, there is a possibility that the partition 6B and surrounding elements are damaged.

In a case where the partition 6B is not divided into a plurality of segments SG, a resist which is provided after the partition 6B (for example, the resist for patterning the rib layer 5) may have a formation defect. Specifically, as the expansion of the resist is blocked by the partition 6B, a portion which is not sufficiently filled with the resist could be generated under the upper portion 62 of the partition 6B. In this case, there is a possibility that the space in which the resist is not provided expands and bursts when the resist is dried under a reduced-pressure environment.

In a case where the partition 6B consists of a plurality of segments SG which are spaced apart from each other via the gap G like this embodiment, as the partition 6B which is a conductive body is divided into a plurality of portions, the electrostatic discharge described above is not easily generated. In addition, since the resist easily expands through the gap G, the shape defect of the resist can be also prevented.

If width Wg is too great, the effect of preventing the removal of the stacked films FL1, FL2 and FL3 could be reduced. In this respect, as a result of verification, the inventor confirms that the removal of the stacked films FL1, FL2 and FL3 can be satisfactorily prevented when width Wg is less than or equal to 40 μm as described above.

Thus, the configuration of the embodiment can prevent the removal of the stacked films FL1, FL2 and FL3, electrostatic discharge or the shape defect of the resist and improve the yield at the time of manufacturing the display device DSP and the mother substrate MB.

The shape or layout form of the segments SG constituting the partition 6B is not limited to the example shown in FIG. 6. The following second to eighth embodiments disclose other examples which could be applied to the segments SG.

### Second Embodiment

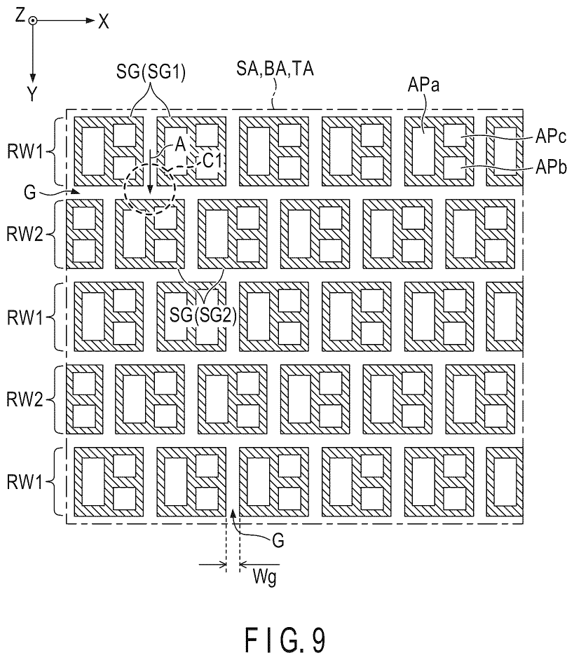

FIG. 9 is the schematic plan view of a plurality of segments SG according to the second embodiment. In this embodiment, the segments SG which are adjacent to each other in a Y-direction are misaligned in an X-direction. Specifically, in the example of FIG. 9, a first column RW1 which includes a plurality of segments (first segments) SG1 arranged in the X-direction (first direction) and a second column RW2 which includes a plurality of segments (second segments) SG2 arranged in the X-direction are formed. In the Y-direction (second direction), the first and second columns RW1 and RW2 are alternately provided.

The segments SG1 and SG2 are misaligned in the X-direction. By this configuration, for example, as shown in the portion surrounded by dashed circle C1, a gap G which is surrounded by the segments SG1 and SG2 is formed into a T-shape.

In a case where the stacked films FL1, FL2 and FL3 are removed in the gap G as described above, if the gap G is linear, this removal easily expands to a wide range. However, if the gap G has a T-shape, for example, in a case where the removal expands to the direction shown by arrow A in FIG. 9, the segment SG2 located in the expansion direction prevents a further spread of the removal.

In the example of FIG. 9, the segments SG which are adjacent to each other in the Y-direction are misaligned in the X-direction. As another example, the segments SG which are adjacent to each other in the X-direction may be misaligned in the Y-direction.

### Third Embodiment

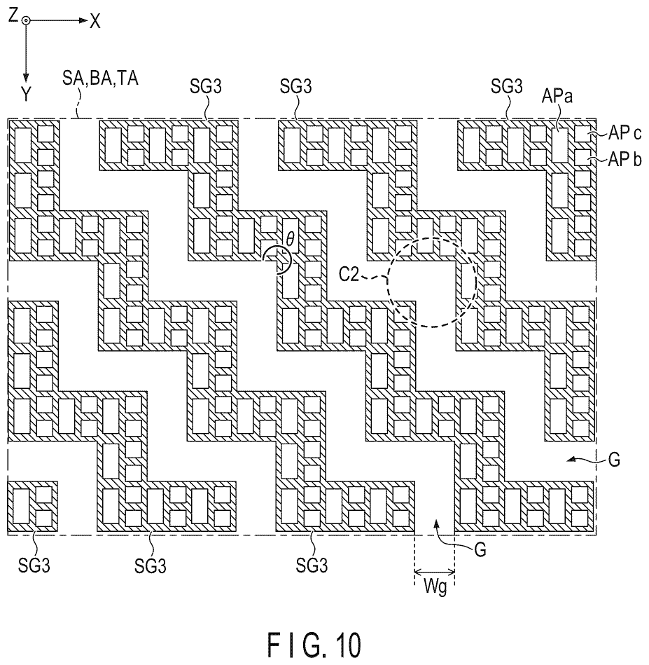

FIG. 10 is the schematic plan view of a plurality of segments SG (hereinafter, referred to as segments SG3) according to the third embodiment. Each segment SG3 has a step-like (zigzag) planar shape.

Each segment SG3 has a large number of apertures APa, APb and APc. Each segment SG3 has a polygonal shape having an interior angle θ which is greater than 180°. In the example of FIG. 10, the interior angle θ is 270°.

A step-like gap G is defined between adjacent segments SG3. Specifically, the gap G is bent into an L-shape as shown in the portion surrounded by dashed circle C2. Even this configuration can prevent the removal of the stacked films FL1, FL2 and FL3 from spreading along the gap G.

The gap G has, for example, a uniform width Wg as a whole. Width Wg should be preferably less than or equal to 40 μm in a manner similar to that of the first embodiment. It should be noted that width Wg may be partially nonuniform.

### Fourth Embodiment

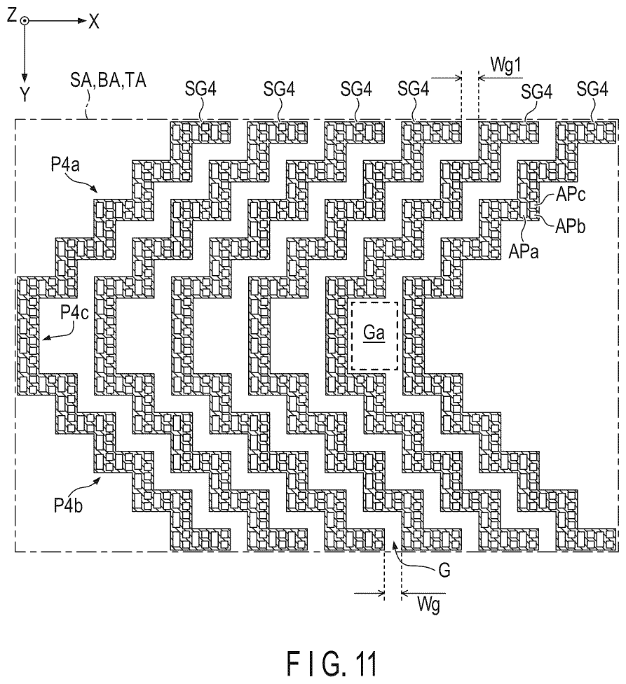

FIG. 11 is the schematic plan view of a plurality of segments SG (hereinafter, referred to as segments SG4) according to the fourth embodiment. Each segment SG4 has a V-shape as seen in plan view. Specifically, each segment SG4 has a first part P4a, a second part P4b and a third part P4c which connects these first part P4a and second part P4b to each other. The first part P4a and the second part P4b extend in directions different from each other. The extension directions of the first part P4a and the second part P4b intersect with, for example, an X-direction and a Y-direction.

Each of the first part P4a and the second part P4b has a step-like shape in a manner similar to that of the segments SG3 shown in FIG. 10. The first part P4a, the second part P4b and the third part P4c have a large number of apertures APa, APb and APc.

The segments SG4 are arrayed such that the first parts P4a are arranged in the X-direction, and the second parts P4b are arranged in the X-direction, and the third parts P4c are arranged in the X-direction. A gap G has a step-like shape between the first parts P4a of adjacent segments SG4 and between the second parts P4b of adjacent segments SG4.

In the example of FIG. 11, the width of the gap G is increased in an area Ga located between the third parts P4c of adjacent segments SG4. For example, width Wg of the gap G is less than or equal to 40 μm excluding the area Ga. It should be noted that the shape of each segment SG4 may be determined such that width Wg is uniform over the enter gap G.

### Fifth Embodiment

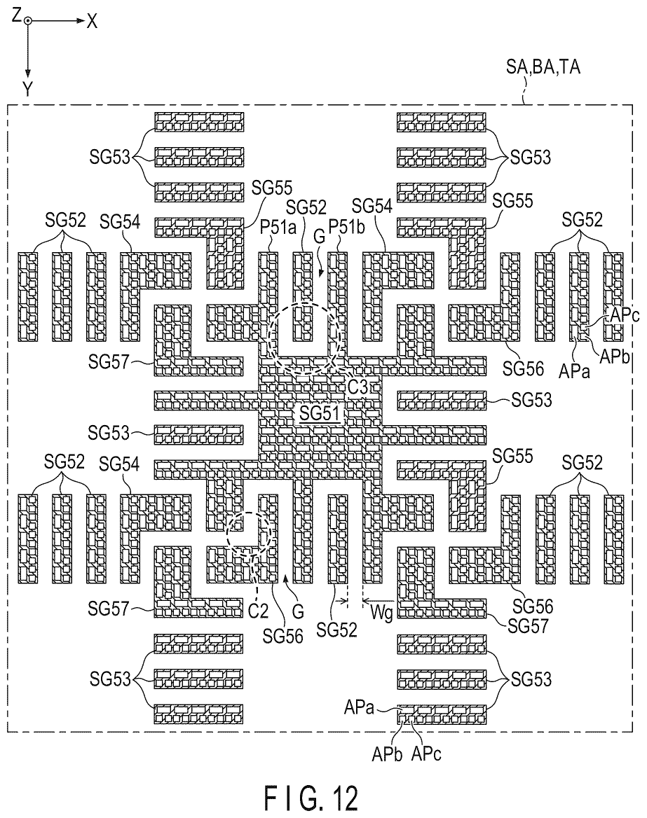

FIG. 12 is the schematic plan view of a plurality of segments SG according to the fifth embodiment. In the example of FIG. 12, a plurality of types of segments SG51 to SG57 having different shapes are provided. Each of the segments SG51 to SG57 has a large number of apertures APa, APb and APc.

The segment SG51 has a complicated planar shape in which a large number of arm portions protrude from the rectangular center portion. Each segment SG52 has a rectangular shape which is long in a Y-direction. Each segment SG53 has a rectangular shape which is long in an X-direction. Each segment SG54 has an L-shape which has a portion extending in the X-direction and a portion extending in the Y-direction. Each segment SG55 has an L-shape which is obtained by rotating each segment SG54 90° clockwise. Each segment SG56 has an L-shape which is obtained by rotating each segment SG55 90° clockwise. Each segment SG57 has an L-shape which is obtained by rotating each segment SG56 90° clockwise. Each of the segments SG51 and SG54 to SG57 has a polygonal shape having at least one interior angle which is greater than 180°, specifically, an interior angle of 270°, in a manner similar to that of the segments SG3 etc.

As an example of the arm portions of the segment SG51, this specification focuses attention on first and second arm portions P51a and P51b extending in the Y-direction. In FIG. 12, the segment SG52 is provided between the first arm portion P51a and the second arm portion P51b. By this configuration, a U-shaped gap G is defined as shown in the portion surrounded by dashed circle C3.

In addition to this portion, a large number of U-shaped gaps G like this portion are defined around the segment SG51. Further, in the example of FIG. 12, L-shaped gaps G are defined in several portions as shown in the portion surrounded by dashed circle C2. In the U-shaped gaps G, in a manner similar to that of the L-shaped and T-shaped gaps G, the expansion of the removal of the stacked films FL1, FL2 and FL3 can be prevented.

In this embodiment, similarly, it is preferable that width Wg of each gap G defined between adjacent two segments of the segments SG51 to SG57 should be less than or equal to 40 μm. Width Wg may be uniform over the entire gap G or may be partially nonuniform.

### Sixth Embodiment

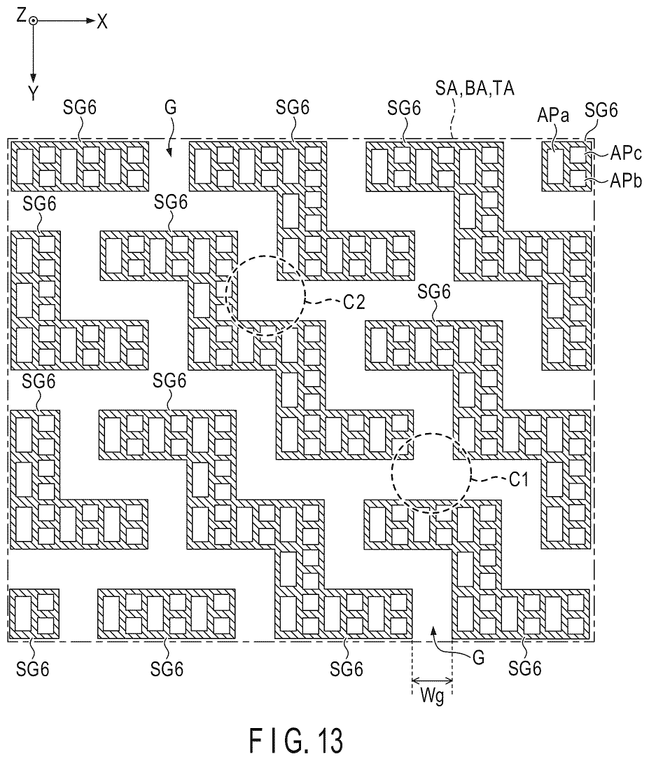

FIG. 13 is the schematic plan view of a plurality of segments SG (hereinafter, referred to as segments SG6) according to the sixth embodiment. Each segment SG6 has a step-like planar shape which is shorter than the segments SG3 shown in FIG. 10.

Each segment SG6 has a large number of apertures APa, APb and APc. Each segment SG6 has a polygonal shape having a plurality of interior angles which are greater than 180°, specifically, a plurality of interior angles of 270°, in a manner similar to that of the segments SG3 etc.

In the example of FIG. 13, a T-shaped gap G is defined in each portion where three segments SG6 are adjacent to each other as shown in the portion surrounded by dashed circle C1. An L-shaped gap G is defined between adjacent two segments SG6 as shown in the portion surrounded by dashed circle C2. In this embodiment, similarly, width Wg of the gap G should be preferably less than or equal to 40 μm. Width Wg may be uniform over the entire gap G or may be partially nonuniform.

### Seventh Embodiment

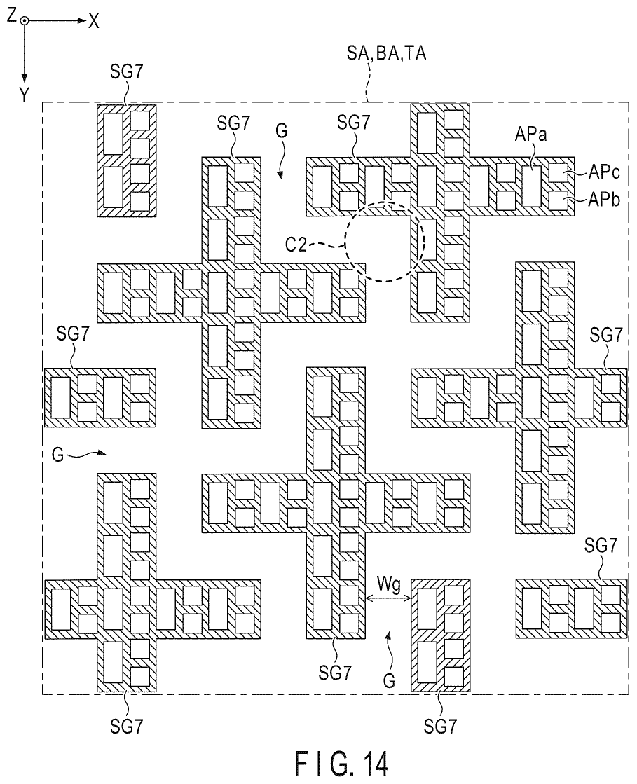

FIG. 14 is the schematic plan view of a plurality of segments SG (hereinafter, referred to as segments SG7) according to the seventh embodiment. Each segment SG7 has a cruciform planar shape. The segments SG7 which are adjacent to each other are misaligned in both an X-direction and a Y-direction.

Each segment SG7 has a large number of apertures APa, APb and APc. Each segment SG7 has a polygonal shape having a plurality of interior angles which are greater than 180°, specifically, a plurality of interior angles of 270°, in a manner similar to that of the segments SG3.

In the example of FIG. 14, an L-shaped gap G is defined between adjacent segments SG7 as shown in the portion surrounded by dashed circle C2. In this embodiment, similarly, width Wg of the gap G should be preferably less than or equal to 40 μm. Width Wg may be uniform over the entire gap G or may be partially nonuniform.

### Eighth Embodiment

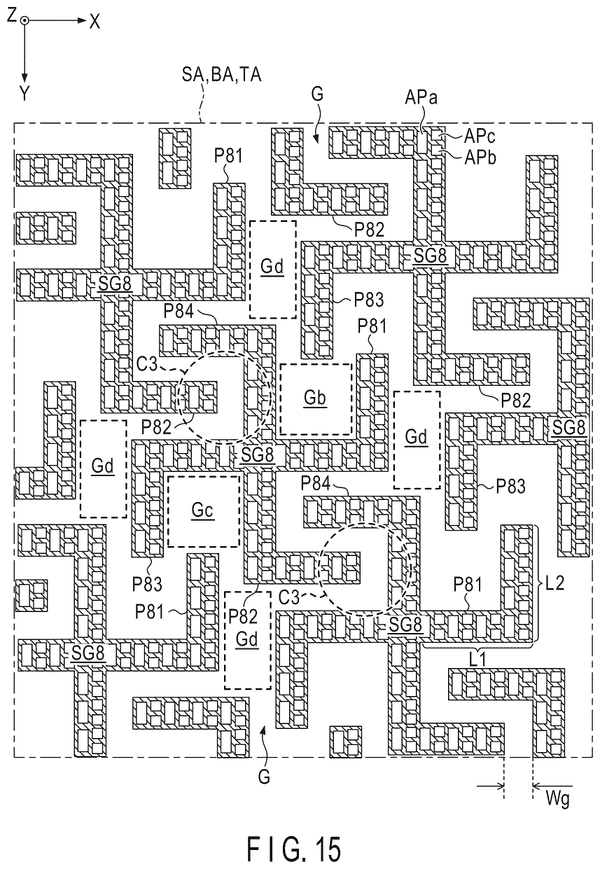

FIG. 15 is the schematic plan view of a plurality of segments SG (hereinafter, referred to as segments SG8) according to the eighth embodiment. Each segment SG8 has a swastika-like planar shape. Specifically, each segment SG8 has four arm portions P81 to P84 extending in different directions.

The arm portion P81 has an L-shape which has a linear portion L1 extending in an X-direction and a linear portion L2 extending in a Y-direction. In the example of FIG. 15, the lengths of the linear portions L1 and L2 are equal to each other. The arm portion P82 has an L-shape which is obtained by rotating the arm portion P81 90° clockwise. The arm portion P83 has an L-shape which is obtained by rotating the arm portion P82 90° clockwise. The arm portion P84 has an L-shape which is obtained by rotating the arm portion P83 90° clockwise. The segments SG8 which are adjacent to each other are misaligned in both the X-direction and the Y-direction.

Each segment SG8 has a large number of apertures APa, APb and APc. Each segment SG8 has a polygonal shape having a plurality of interior angles which are greater than 180°, specifically, a plurality of interior angles of 270°, in a manner similar to that of the segments SG3 etc.

Between the arm portions P81 and P82 of each segment SG8, part of the arm portion P84 of another segment SG8 is located. Between the arm portions P83 and P84 of each segment SG8, part of the arm portion P82 of another segment SG8 is located. By these configurations, U-shaped gaps G are defined as shown in the portions surrounded by dashed circles C3.

In the example of FIG. 15, between the arm portions P81 and P84 of each segment SG8, the other segments SG8 are not located. Similarly, between the arm portions P82 and P83 of each segment SG8, the other segments SG8 are not located.

In the example of FIG. 15, the gap G consists of a plurality of portions having different widths. Specifically, compared to the portions surrounded by dashed circles C3, the width of the gap G is increased in an area Gb located between the arm portions P81 and P84 of each segment SG8, an area Gc located between the arm portions P82 and P83 of each segment SG8 and each area Gd surrounded by the arm portions P81 to P84 of different segments SG8.

Width Wg of the gap G should be preferably less than or equal to 40 μm in a large part of the gap G. For example, width Wg of the gap G may be less than or equal to 40 μm excluding the areas Gb, Gc and Cd.

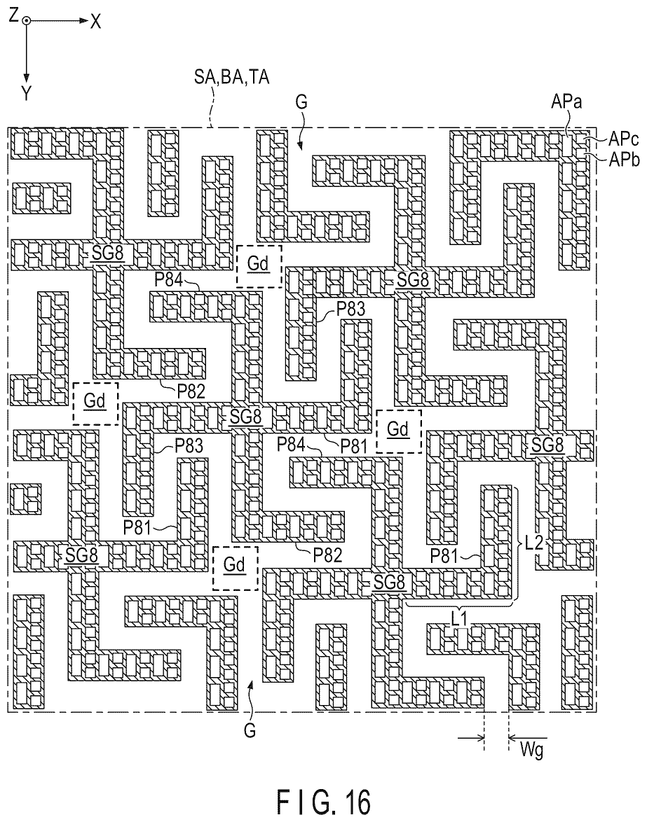

FIG. 16 is a schematic plan view showing another example of the layout form of the segments SG8. The shape of each segment SG8 shown in this figure is similar to that of FIG. 15. However, in the example of FIG. 16, the areas Gb and Cc shown in FIG. 15 are lost, and further, each segment SG8 is provided such that the size of each area Gd is reduced.

Specifically, in the example of FIG. 16, between the arm portions P81 and P84 of each segment SG8, part of the arm portion P83 of another segment SG8 is located. Further, between the arm portions P82 and P83 of each segment SG8, part of the arm portion P81 of another segment SG8 is located.

When the areas Gb and Gc are lost in this manner, the number of portions having a U-shape can be increased in the gap G. As a result, even if the stacked films FL1, FL2 and FL3 are removed in the gap G, the expansion of the removal is easily suppressed.

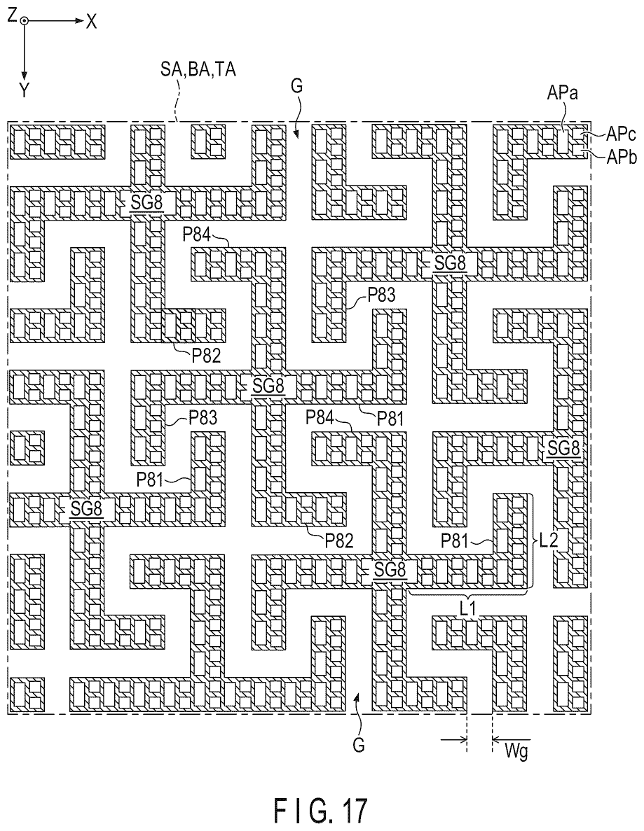

FIG. 17 is a schematic plan view showing yet another example of the layout form of the segments SG8. The shape of each segment SG8 shown in this figure is different from that of FIG. 15 and FIG. 16 in respect that the linear portion L2 is shorter than the linear portion L1 in each of the arm portions P81 to P84.

In the example of FIG. 17, the segments SG8 are provided such that all of the areas Gb, Gc and Gc shown in FIG. 15 are lost. By this configuration, width Wg of the gap G can be made uniform as a whole.

In addition to the first to eighth embodiments described above, various shapes and layout forms can be applied to the segments SG. Two or more of the segments SG disclosed in the embodiments may be provided in at least part of the surrounding area SA, inspection area TA and margin area BA.

Each embodiment assumes a case where the partition 6B (segments SG) is provided in each of the surrounding area SA, the inspection area TA and the margin area BA. As another example, the partition 6B may not be provided in one of the surrounding area SA, the inspection area TA and the margin area BA. When the partition 6B is not provided in the surrounding area SA, the display panel PNL or display device DSP which does not comprise the partition 6B is manufactured.

All of the display devices, mother substrates and manufacturing methods that can be implemented by a person of ordinary skill in the art through arbitrary design changes to the display device, mother substrate and manufacturing method disclosed in the embodiments described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a lower electrode provided in a display area which displays an image;
a rib layer which is provided in the display area and a surrounding area around the display area and has a pixel aperture overlapping the lower electrode;
a first partition provided above the rib layer in the display area;
an organic layer which is in contact with the lower electrode through the pixel aperture and emits light based on application of voltage;
an upper electrode which covers the organic layer and is in contact with the first partition; and
a second partition provided above the rib layer in the surrounding area, wherein
each of the first partition and the second partition includes a lower portion provided above the rib layer and an upper portion having an end portion protruding from a side surface of the lower portion,
the second partition includes a plurality of segments spaced apart from each other, and
each of the segments has a plurality of apertures.

2. The display device of claim 1, wherein
at least part of a gap defined between the segments has a width which is less than or equal to 40 μm.

3. The display device of claim 1, wherein
at least one of the segments has a plurality of apertures having different sizes.

4. The display device of claim 1, wherein
the segments include:
a first column including a plurality of first segments arranged in a first direction; and
a second column including a plurality of second segments which are adjacent to each other in a second direction intersecting with the first direction with respect to the first column and are arranged in the first direction, and
the first segments and the second segments are misaligned in the first direction.

5. The display device of claim 1, wherein
at least one of the segments has a polygonal shape having an interior angle which is greater than 180°.

6. The display device of claim 1, wherein
at least one of the segments has a step-like shape.

7. The display device of claim 1, wherein
at least one of the segments is cruciform.

8. The display device of claim 1, wherein
at least one of the segments includes a first arm portion and a second arm portion, and
part of another one of the segments is provided between the first arm portion and the second arm portion.

9. The display device of claim 1, wherein
at least one of the segments has a plurality of arm portions extending in different directions.

10. The display device of claim 1, wherein
a gap defined between the segments includes a portion having a T-shape, an L-shape or a U-shape.

11. A mother substrate for a display device, the mother substrate comprising:
a plurality of panel portions each of which includes a display area and a surrounding area around the display area;
a margin area around the panel portions;
a lower electrode provided in the display area;
a rib layer which has a pixel aperture overlapping the lower electrode;
a first partition provided above the rib layer in the display area;
an organic layer which is in contact with the lower electrode through the pixel aperture and emits light based on application of voltage;
an upper electrode which covers the organic layer and is in contact with the first partition; and
a second partition provided above the rib layer in at least one of the surrounding area and the margin area, wherein
each of the first partition and the second partition includes a lower portion provided above the rib layer and an upper portion having an end portion protruding from a side surface of the lower portion,
the second partition includes a plurality of segments spaced apart from each other, and
each of the segments has a plurality of apertures.

12. The mother substrate of claim 11, wherein
at least part of a gap defined between the segments has a width which is less than or equal to 40 μm.

13. The mother substrate of claim 11, wherein
at least one of the segments has a plurality of apertures having different sizes.

14. The mother substrate of claim 11, wherein
the segments include:
a first column including a plurality of first segments arranged in a first direction; and
a second column including a plurality of second segments which are adjacent to each other in a second direction intersecting with the first direction with respect to the first column and are arranged in the first direction, and
the first segments and the second segments are misaligned in the first direction.

15. The mother substrate of claim 11, wherein
at least one of the segments has a polygonal shape having an interior angle which is greater than 180°.

16. The mother substrate of claim 11, wherein
at least one of the segments has a step-like shape.

17. The mother substrate of claim 11, wherein
at least one of the segments is cruciform.

18. The mother substrate of claim 11, wherein
at least one of the segments includes a first arm portion and a second arm portion, and
part of another one of the segments is provided between the first arm portion and the second arm portion.

19. The mother substrate of claim 11, wherein
at least one of the segments has a plurality of arm portions extending in different directions.

20. The mother substrate of claim 11, wherein
a gap defined between the segments includes a portion having a T-shape, an L-shape or a U-shape.
